(19) United States
(12) Patent Application Publication
(10) Pub. No.: US 2009/0032925 A1
(43) Pub. Date: Feb. 5, 2009

(54) PACKAGING WITH A CONNECTION STRUCTURE

(76) Inventor: Luke G. England, Boise, ID (US)

Correspondence Address: Charles B. Brantley;Mail Stop 1-525, Micron Technology, Inc., 8000 S. Federal Way, Boise, ID, 83716, US

(21) Appl. No.: 11/831,572

(22) Filed: Jul. 31, 2007

(51) Int. Cl. H01L 23/02; H01L 21/00

(52) U.S. Cl. 257/680; 257/738; 438/116; 257/E23.023; 257/E23.18

(57) ABSTRACT

In a package including an image sensor die with an interconnect extending therethrough, a cover allowing light to pass is coupled to the die using at least one solder ball and a corresponding number of pads on each of the cover and die. Such pads are added to the cover despite the die's interconnect allowing contact with external devices at a location distal from the cover. The solder balls help govern the parallel orientation (or an alternate orientation) between the die and the cover. In addition, connectors other than solder balls may be used; multi-layered covers with connectors between the layers may be used; and packages other than imagers may be assembled.

### TECHNICAL FIELD

Embodiments of the invention relate generally to semiconductor device packaging. More specifically, embodiments of the invention relate to imager device packaging.

### BACKGROUND

Imagers are devices configured to sense radiation and generate signals corresponding to an image based on that radiation. Imagers include complimentary metal oxide semiconductor (CMOS) imagers as well as charge coupled devices (CCDs). Such imagers may be constructed on and within a semiconductor substrate. These imagers may also be packaged in order to protect them from damage and contamination. Packaging may also redistribute an imager die's signal access points for easier communication with other devices. At least one portion of the package may be transparent to the radiation wavelengths the imager is configured to detect. For example, a glass lens or flat glass panel may be placed over a CMOS imager configured to detect visible light.

In terms of attaching the glass to the die or to other parts of the package, background art includes U.S. Pat. No. 7,141,869, which suggests using a ring of solder bonded to a ring-shaped contact on the imager die as well as to a similarly-shaped contact, on the glass. Patent '869 describes previous glass attachment attempts using a solid ring of solder and warns that air trapped between the ring, glass, and die may increase solder joint failure. Patent '869 proposes using an initial open ring configuration that is eventually closed with polymer Patent '869 also generally warns about how dispensing techniques and materials may contaminate the image sensing area. ('869 at col. 10-11.)

This current application further notes that techniques involving dispensing material from a needle or similar device may cause “spattering.” This may, in turn, result in contaminating the light sensitive portions of the imager. In addition, a sealant, around the Sight sensitive portions of the imager may subsequently introduce contaminants into the sealed area by way of outgassing.

Returning to '869, its glass has conductive traces and contacts thereon. As for '869's imager die, illustrations depict conductive contacts only on the side of the die facing the glass. '869 refers to prior art wherein contacts are on the opposite side of the die, but '869 teaches that providing such involves critical drawbacks including the complexity of the structure and process, high manufacturing costs, and low yield. ('869 at col 2-3; FIG. 3.) As a result, signals from a contact on '869's imager die face travel through a solder ball to a contact on the glass; a conductive trace extends from the glass contact, along the surface of the glass, to a bigger contact on the glass; that bigger contact is in turn coupled to a bigger solder ball configured to communicate with external devices.

U.S. Pat. No. 6,943,423 also discloses an imager die connected to glass by way of solder joints between contacts on the glass and contacts on the side of the imager die facing the glass. As in '869, '423's illustrations depict conductive contacts only on the side of its die facing the glass, '423 refers to the same prior art discussed '869, wherein contacts on the opposite side of the die involve many more process steps. (Compare '869 at col. 2-3, FIG. 3 with '423 at col. 2, FIG. 4. It should also be noted '869 and '423 share the same inventor and assignee.) Concerning the contacts on '423's glass, three sets of contacts are described: a first set for electrical interconnection with the die; a second set for electrical interconnection with external circuitry; and a third set for electrical interconnection with passive components such as decoupling capacitors. Patent '423 also teaches isolating the light sensitive portions of the imager with flux around the solder joints.

U.S. Pat. No. 6,864,116 ultimately seals the light sensitive portions of its imager using a polymer dust seal. Patent '116 also discloses conductive paths extending from contacts on the die side facing the glass, through solder bumps, to contacts on the glass, along conductive traces on the surface of the glass, to bigger contacts on the glass and bigger solder bumps configured to communicate with external devices. As in the patents discussed above '116's illustrations depict conductive contacts only on the side of its die facing the glass. '116 refers to the same prior art discussed '869 and '423 concerning contacts on the opposite side of the die; and '116 raises similar criticisms of such a configuration. (See '116 at col. 1-2; FIG. 2.)

Still other imager die include a contact in addition or alternative to a contact facing the transparent component. Such imager die include those having a conductor extending through the die in a direction generally perpendicular to the plane defined by the contact. U.S. Pat. No. 7,199,439 discloses such an imager die. Such a conductor may be referred to in the art as a “through silicon via,” a “through silicon interconnect,” or a “through wafer interconnect” (assuming the interconnect was formed on a wafer-scale workpiece). That conductor may be coupled to a conductive contact on the die side facing away from the glass. That contact may, in turn, be directly connected to a solder ball. As an addition or alternative, that contact may be coupled to a conductive trace leading to another contact with a solder ball thereon.

Accordingly, there is a need in the art for improved alternatives for packaging those types of imager die as well.

### BRIEF DESCRIPTION OF THE DRAWINGS

FIG. 1A is a cross-sectional view of an embodiment of the invention.

FIG. 1B is a perspective view of that embodiment.

FIGS. 2-5 depict embodiments directed to forming a device.

FIGS. 6-8 picture device embodiments of the invention.

FIG. 9 is a top-down view of a wafer used in an embodiment of the invention.

FIGS. 10-18 picture device embodiments of the invention.

### DETAILED DESCRIPTION OF THE EMBODIMENTS

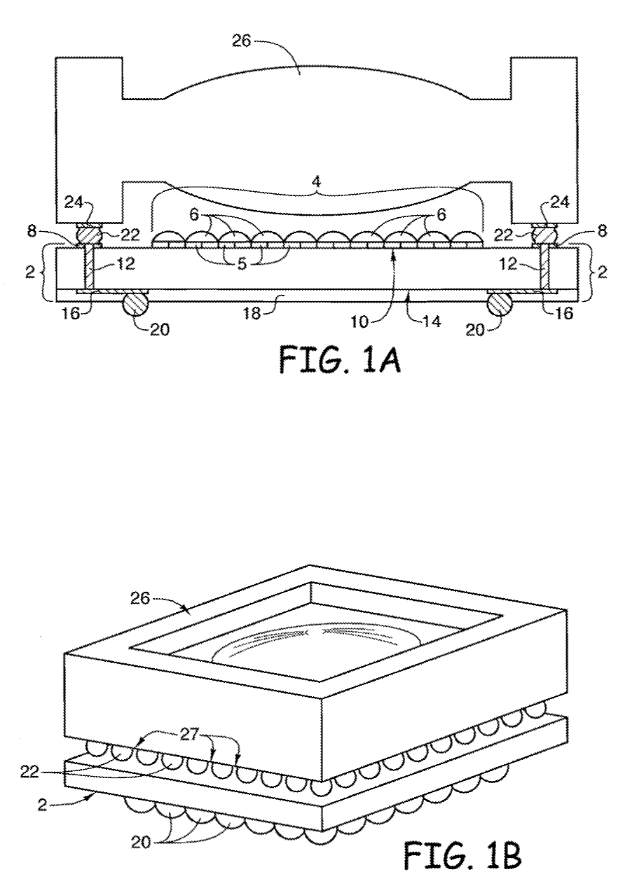

FIG. 1A illustrates an embodiment of the invention, wherein the embodiment includes a die 2. For purposes of explanation and not limitation, the die 2 is assumed to be a CMOS imager formed in and on a workpiece made of a semiconductor such as silicon. The die 2 may support a layer of patterned resist which forms a color filter array 4. The color filter array 4 may be divided into segments 5, wherein each segment 5 may be colored to detect a certain wavelength of visible light. A microlens 6 may be located over one or more segments 5 of the color filter array 4. Other components may be fabricated within the die 2, such as at least one photodiode (not shown) in the form of a doped silicon region. That region may coincide with a depth corresponding to where a photon having a certain wavelength may be absorbed by the silicon, thereby generating an electron-hole pair. Also formed on and within the die 2 include transistors and capacitors (not shown) respectively configured to move and store the generated electron. Still other transistors may be included as part of peripheral circuitry (not shown). Eventually, an electric signal resulting from the absorption of a photon may end up at an electrically conductive contact 8 on the surface 10 of the die 2. This contact 8 is coupled to an interconnect 12 extending through the die 2 in a direction generally perpendicular to the plane defined by the surface 10 of the die 2.

The interconnect 12 may be formed using techniques known in the art. One such technique involves removing material, including silicon, under the contact 8 (and perhaps removing a portion of the material forming contact 8 itself). Removal may be accomplished using a dry etch, wet etch, laser, or combinations thereof. Further, the removal process may be begin at the surface 10 or the opposing surface 1.4 of the die 2. If the removal process begins at the surface 10, the removal process may not extend ail the way through the die; and the surface 14 of the die 2 may be ground away until the opening is exposed.

An electrical insulator (not shown) may be used to line the opening defined by the removal process. An electrical conductor may then extend through the opening. The conductor may fill the opening. Alternatively, the conductor may only line the opening. In such an alternative, a non-conductor may be added to fill the remainder of the opening for support. As still another alternative, a wire may extent through the opening using techniques such as those taught in U.S. Published Application 2006/0228825. Formation of interconnect 12 may occur before, during, or after fabricating the imager components discussed above.

The interconnect 12 extends to the surface 14 of the die 2. Electrical connection with external devices may be established at that point, but often the connection point, is relocated in order to accommodate the conductive terminals of the external devices. As a result, a conductive redistribution trace 16 may be added. Again, techniques are known in the art for adding such. For example, a continuous electrical conductor may be added to the surface 14 of the die 2 and then etched according to a patterned resist. Alternatively, a damascene process may be employed, wherein a continuous electrical insulator may be added to the surface 14 of the die 2, with trenches etched from the insulator according to a patterned resist. An electrical conductor may then be added in the trenches.

Regardless of how the trace 16 is formed, it may be covered for the most part by a passivation layer 18, which exposes the trace 16 in at least one region where contact with an external device may be desired. In that region, a solder ball 20 may be added.

Despite the connection provided by solder ball 20 on the side 14 of the die 2 facing away from the glass 26, this embodiment adds a solder ball 22 to the contact 8 on the surface 10 of the die 2 facing the glass 26. Further in spite of the connection provided by solder ball 20, a conductive contact 24 is added to the glass 26.

Adding the conductive contact 24 to the glass 26 may be accomplished using techniques known in the art. One such technique involves sputtering aluminum or copper onto the glass 26. Photoresist may be added and patterned to cover the contact sites, and the uncovered metal may be etched. If aluminum is sputtered, a nickel-palladium or nickel-palladium-gold alloy may be electrolessly plated so that the contact 24 may be sufficiently wettable with respect to the solder bail 22. If copper is sputtered, it alone may exhibit sufficient wettability, and plating may not be performed. Given the connection provided by solder ball 20 on the side 14 of the die 2 facing away from the glass 26, a conductor extending from the conductive contact 24 and along glass 26 for connection with external devices may not be needed; and the time, money, and effort of adding such a conductive extension may be saved or applied elsewhere in this embodiment. As a result, the contact 24 of this embodiment may be considered to be in “pad” form—defining no predominant axis of extension, in contrast to a trace or a trace/pad combination. In this embodiment, the pad is generally square-shaped from a top-down point of view.

The conductive contact 24 is located on glass 26 such that, when the glass 26 and die 2 are combined, the contact 24 is aligned with the solder ball 22. Adhesion between the glass 26 and the die 2 may be assisted by the cohesion of solder ball 22 as well as the wettability of solder ball 22 with respect to the conductive contact 24 and the contact 8/interconnect 12.

Moreover, it is noted that commercially available solder balls tend to be sufficiently consistent in size. For example, solder balls touted as having a certain size may vary by only five microns in diameter. As a result, the solder ball 22 may assist in keeping the glass 26 generally parallel to the die 2. Given the length and width of the glass 26 and die 2, as well as the size of the solder ball 22, some embodiments use more than one solder ball 22 to assist in keeping the glass 26 generally parallel to the die 2. In addition, some embodiments locate the solder balls 22 toward the periphery of the glass 26 and die 2. In such embodiments, the parallel nature of the glass 26 and die 2 may be established to the point where the glass 26 height from the die 2 may differ by at most 5 microns from one end of the glass 26 to the other.

Still further, known techniques for placing solder bails tend to be a relatively clean process—without the spattering that may be associated with techniques using needles or other dispensers.

Moreover given the size and location of the of the solder balls 22, adjacent solder balls 22 define an opening 27 therebetween, as seen in FIG. 1B. In at least one embodiment, that opening is maintained at least to the point where the die 2/glass 26 combination is attached to another substrate, such as a printed circuit board (PCB) (not shown) configured to fit inside a camera or other product. Once the solder balls 22 have been placed between the die 2 and glass 26 and experienced a reflow temperature, they may experience such temperatures again briefly (10-20 seconds, for example) during reliability testing or while the die 2/glass 26 combination is attached to a PCB. If flux was used in the soldering process, some outgassing may occur, but the opening 27 defined by the solder balls 22 may prevent the gas from being trapped near the light-sensitive portions of the die 2. If gold is used as a pad material, there may be no flux and therefore no outgassing. In addition, the opening 27 defined by the solder balls 22 may assist in some embodiments with undesirable cracking or flexing if the die 2/glass 26 combination, either alone or as part of larger product, is subjected to a pressure change.

Once the die 2/glass 26 combination is attached to a PCB, underfill may or may not be added between the die 2 and the PCB. Additional covering (not shown) may be placed around the die 2/glass 26/PCB in preparation for (or as part of) incorporating that combination into a larger product. Such covering may help prevent contamination from passing through the opening 27 defined by adjacent solder balls 22 to the light-sensitive portions of the imager.

Furthermore, even though the contacts 24 on the glass 26 and the solder balls 22 do not carry signals to external devices, such components in at least some embodiments may address coefficient of thermal expansion (CTE) mismatch. Once the die 2/glass 26 combination is attached to a PCB and heated, there may be a tendency for the die 2 to expand more or faster than the PCB. The result may be a tearing of the solder ball 20. However, the contacts 24 on the glass 26 and the solder balls 22 in some embodiments may help the glass 26 to restrain the thermal expansion of die 2, thereby helping to maintain the integrity of solder ball 20 and the reliability of the product.

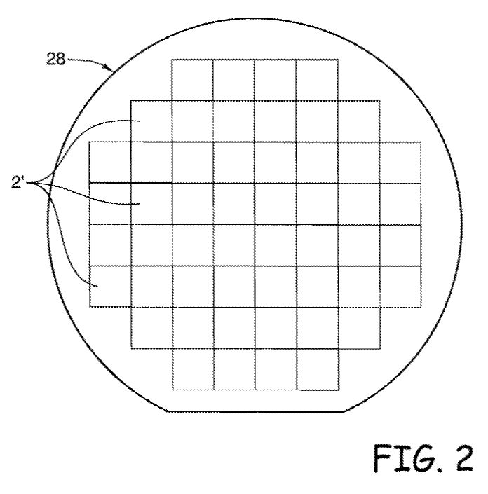

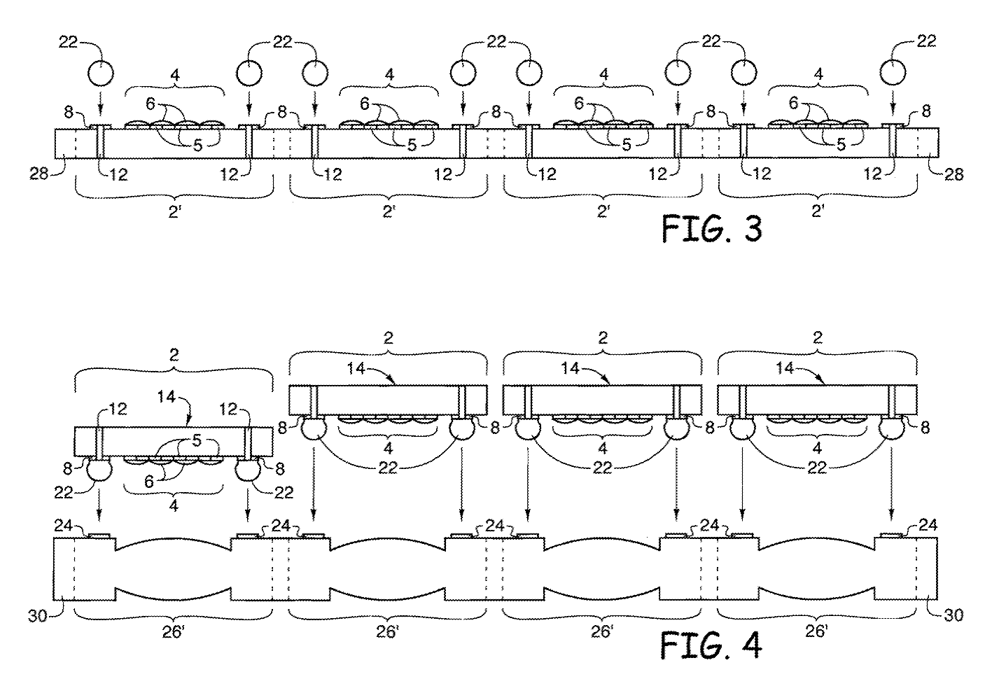

To further detail an embodiment of the invention concerning a method of forming the devices addressed above, a plurality of imagers may be formed on and in a silicon substrate in the form of a wafer, which may be generally circular in shape from a top-down view. Wafers that are commercially available as of the time of writing this application include those having a diameter of 200 mm or 300 mm. FIG. 2 illustrates a wafer 28 comprising at least one die site 2′. FIG. 3 illustrates the wafer 28 after a certain amount of processing, where color filter array 4; microlenses 6; doped regions, circuitry including transistors and capacitors (not shown); contacts 8; and interconnects 12 have been added at or within a plurality of die sites 2′. Solder balls 22 may be added to the contacts 8/interconnects 12. The wafer 28 may then be diced into separate die 2. Testing of the imagers may be performed before and after dicing, and the die 2 that pass testing may be placed on FIG. 4's second wafer 30 comprising at least one glass site 26′ having a scale similar to that of die 2. It is noted that second wafer 30 has undergone a process, such as a molding or patterned etching, to define at least one lens shape. Redistribution traces 16, a passivation layer 18, and solder balls 20 may then be added on the surface 14 of the die 2 using the procedures mentioned above. Alternatively, the redistribution traces 16, passivation layer 18, and solder bails 20 may be added to the die 2 before attaching to the glass and, indeed, before singulating the die 2. Dicing the second wafer 30 may then result in the device illustrated in FIG. 1.

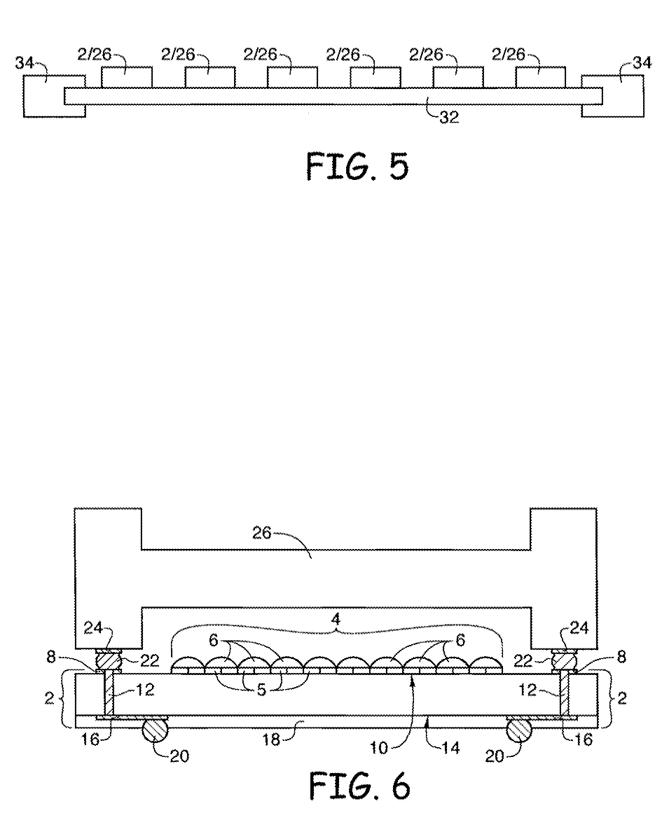

One of ordinary skill in the art can appreciate that additional embodiments of the invention address modifications from the embodiments addressed above. For example, embodiments include those wherein joining the glass 26 and die 2 occur while one or both are in singulated form, partial wafer form, or wafer form. Moreover, “wafer form” may include a workpiece such as that illustrated in FIG. 5, wherein singulated elements (glass 26 or die 2) populate an adhesive (and possibly flexible) material 32 surrounded by a generally rigid frame 34 having a perimeter comparable to that of wafer 28 or 30.

Further, concerning the method of combining the die 2, solder ball 22, and glass 26; the solder ball 22 may be initially added to the contact 24 of glass 26, and the glass 26/solder hall 22 combination may then be connected to the die 2.

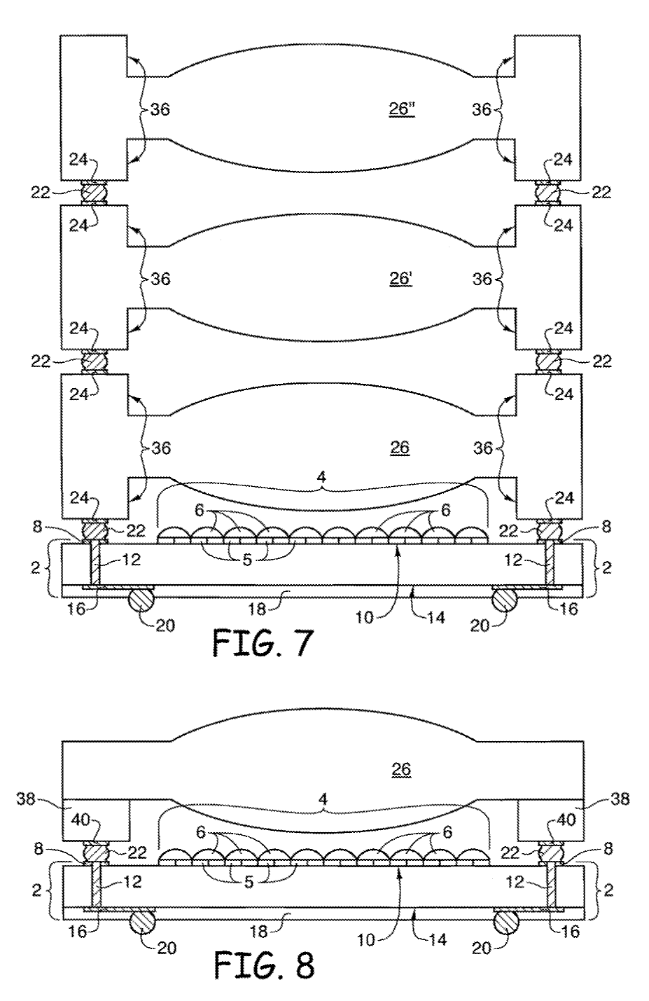

As for the glass 26, embodiments include those pictured in FIG. 6, where the portion of glass 26 over the color filter array 4 is flat rather than defining a curved lens. Moreover, as illustrated in FIG. 7, there may actually be a plurality of glass components 26, 26′, 26″ over the die 2; the glass components may have contacts 24 on the glass top and bottom; and solder balls 22 may be used to help provide parallelism between the neighboring elements.

Adding contacts on the top and bottom may be achieved by processing one side of the glass 26 as described above while it is part of wafer 30, then placing the processed side of wafer 30 on an adhesive carrier, and subsequently processing the now-exposed second side of wafer 30. Glass 26 may then be singulated from the rest of wafer 30 using a dicing technique such as those involving a saw, a laser, or a combination thereof. Regardless of whether the adhesive carrier remains intact or is diced is well, the carrier material may ultimately be delaminated from glass 26, leaving a glass 26 having contacts 24 on both of the major sides. Alternatively, wafer 30 may be singulated after processing one side but before processing the other, and singulated glass 26 components may be placed on a carrier such as that illustrated in FIG. 5 for further processing.

Still further, the glass 26 may not include integral supports 36 spacing the glass 26 from the die 2 or another glass component 26′. Rather, as shown in FIG. 8, the glass 26 may be adhered to a discrete spacer 38 which, in turn, includes an electrically conductive contact 40 such that, when the spacer 38 and die 2 are combined, the contact 40 is aligned with the solder ball 22.

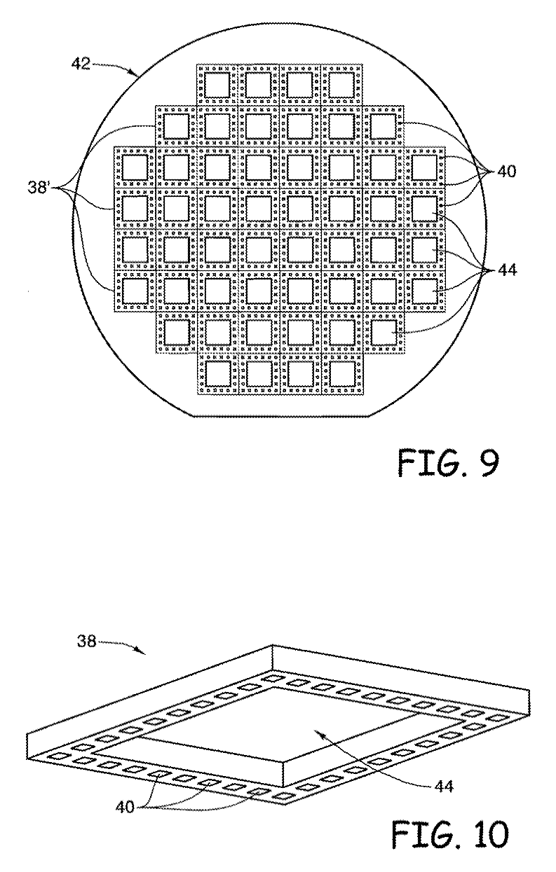

As for fabricating the spacer 38, that may begin with FIG. 9's workpiece 42 having a perimeter comparable to that of wafer 28 or 30. Although not required, the workpiece 42 may be made of silicon, glass, or of some other material that generally matches the CTE of glass 26. A contact 40 may be added at the periphery of a spacer site 38′ of the workpiece 42 in much the same manner contact 24 is added to glass 26. A window 44 may be etched through the workpiece 42 in a location central to the spacer site 38′. Eventually the spacer site 38′ may be singulated from the rest of the workpiece 42, resulting in spacer 38 as illustrated in FIG. 10. However, assembly of the spacer 38 with die 2 and glass 26 may take place while any of those elements are in wafer form, partial wafer form, or die form. Additionally, in joining spacer 38 with die 2, the solder balls 22 may initially be added to either spacer 38 or die 2.

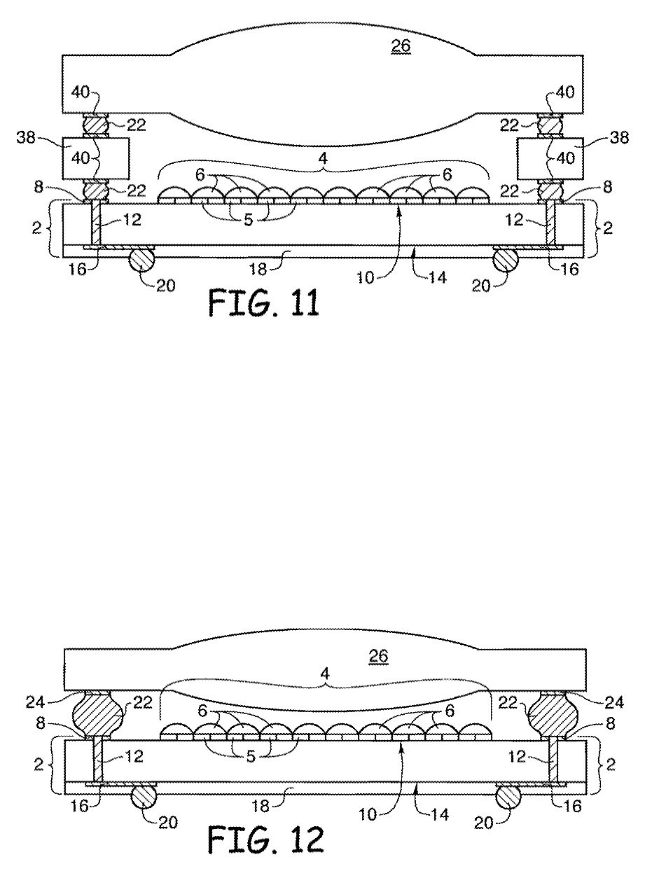

Furthermore, spacer 38 may have contacts 40 on opposite sides, as illustrated in FIG. 11. Adding contacts on the opposite sides may be achieved in a manner similar to that which may be performed in order to process both sides of glass 26, as described above.

In another embodiment, illustrated in FIG. 12, the solder ball 22 acts as a spacer in place of the fabricated structure 38 illustrated in FIGS. 8, 10, and 11 or FIG. 7's integral supports 36 spacing the glass 26.

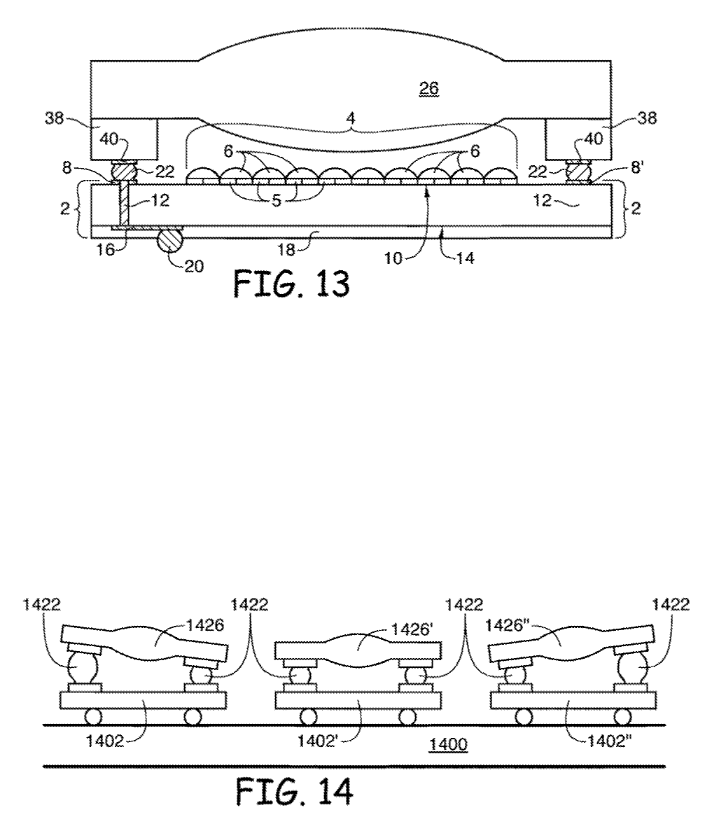

In still another embodiment, a conductive contact 8 may not be needed in a particular region of the die 2 as a terminal for an electric signal. Nevertheless a conductive contact 8 may be added to couple to a solder ball 22. In such an embodiment the contact 8 and interconnect 12 need not be coupled to circuitry on or within the die 2. In yet another embodiment illustrated in FIG. 13, a contact 8′ is added without forming an accompanying interconnect, and the contact 8′ is not coupled to any other portion of the circuitry of the die 2.

As indicated above, embodiments of the invention include connectors that are generally spherical before placing them on the contact of the die 2, glass 26, or spacer 38 and may wet to the contacts thereon. Such connectors include gold/tin-based solder balls, indium-based solder balls, and generally lead free solder balls. In such embodiments, the contacts of the die 2, glass 26, or spacer 38 may be nickel, nickel-palladium, nickel-palladium-gold, or at least include an outer layer of such materials. Still other connectors that may be used in embodiments of the invention include a polymer bead from Sekisui Chemical Company; for example, that polymer bead may be located within a solder ball, in addition, embodiments include those where the connector may be in stud form at least before connection. For instance, in one embodiment a solder stud may be placed on the die 2 or glass 26 (or spacer 38) through electroplating before connection, but that stud may melt into a sphere as part, of the connection process. Another example involves a copper stud, which may stay in pillar form throughout the processes. In such an embodiment, tin may be plated onto the copper stud to wet to the contacts.

As noted above, commercially available solder balls are generally consistent in size in that balls touted has having a certain diameter may vary within tolerances acceptable to embodiments of the current invention. In general, minor variations in solder ball height may be addressed by the force applied by other solder balls. As a result, if one solder ball is slightly larger than others connecting the glass 26 and the die 2, the other balls may cause the larger solder ball to compress to a greater degree, and sufficient parallelism may be maintained in embodiments where such is desired. However, in some embodiments, non-parallelism may be desired. In which case, solder bail size and location may be arranged so that neighboring glass 26, die 2 and spacer 38 elements define an angle. In FIG. 14, glass components 1426, 1426′, and 1426″ are respectively attached to die 1402, 1402′, and 1402″, which are in turn attached to PCB 1400; and die/glass combinations located closer to the perimeter of the PCB 1400 define more of an angle. This is achieved by using different sized solder balls 1422 to attach the glass to its respective die.

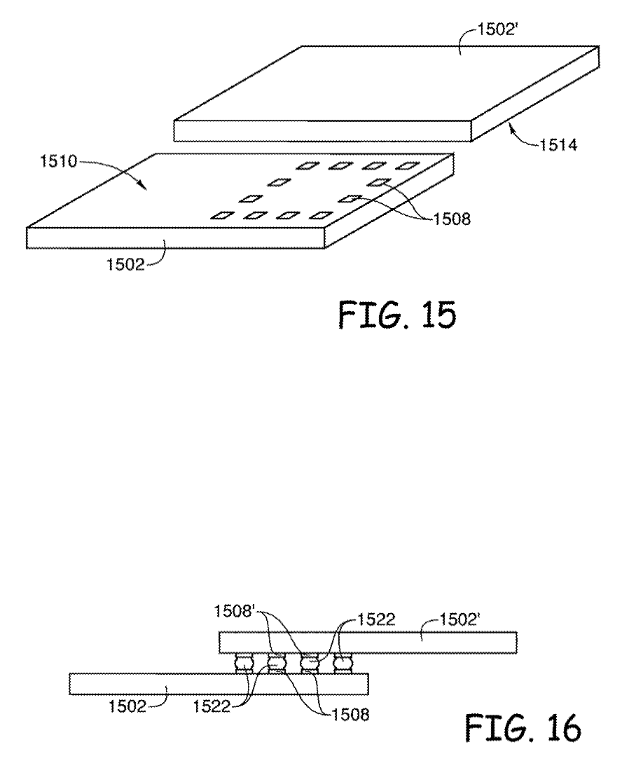

Other embodiments address non-CMOS imager devices, wherein the die 2 may be a CCD or some other radiation-sensing component. Still other embodiments address non-imager devices such as memory. FIG. 15 illustrates a die 1502 that may include predominantly memory, such as DRAM, SRAM, or Flash memory. As an addition or alternative, die 1502 may include microprocessing circuitry. Die 1502 includes conductive contacts (not shown) that may allow electrical communication with other devices. The surface 1510 of die 1502 also includes at least one electrically conductive contact 1508 that may not be coupled to other conductors on or within the die 1502. In the embodiment depicted in FIG. 15, there are a plurality of contacts 1508 on one side of the die 1502. Die 1502′ may be a non-imager device of the same type as that of die 1502, although embodiments include those wherein die 1502 and 1502′ are of different types. Die 1502′ includes a plurality of conductive contacts (not shown in FIG. 15) on its surface 1514 and also on one side of the die 1502′. The conductive contacts on die 1502′ are located thereon such that, when the die 1502 and 1502′ are stacked in a shingle configuration (wherein a die overhangs or at most partially overlaps an underlying die), each die's contacts are aligned with the other die's contacts. FIG. 16 illustrates the contacts 1508′ of die 1502′ connected to the contacts 1508 of die 1502 by way of solder balls 1522. External devices may electrically communicate with the dies 1502 and 1502′ at regions exposed as a result, of the shingle configuration of the stack FIG. 16 may be understood to depict a face-to-face die connection (wherein the circuitry of each die is formed on or near the same surface of the contacts) as well as a face-to-back die connection (wherein the circuitry of one of the die 1502, 1502′ is formed on or near the surface opposite that of the contacts).

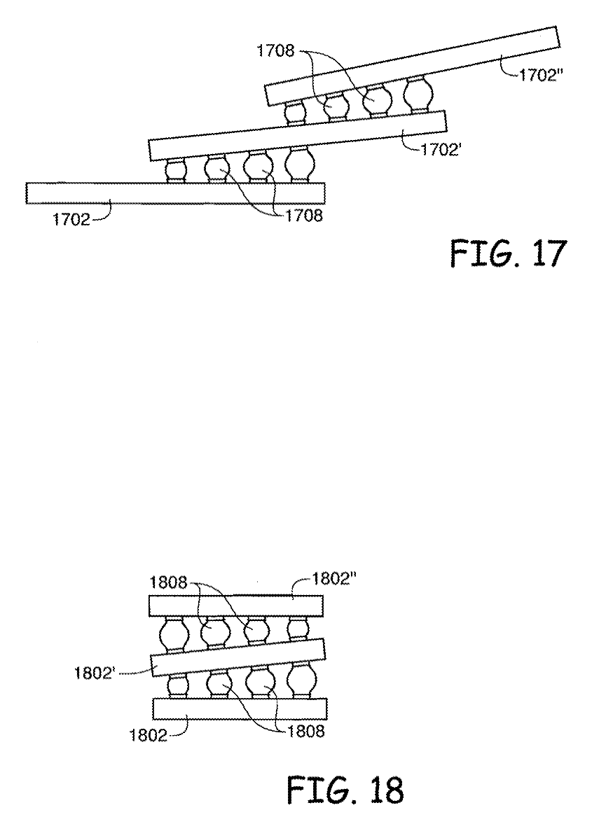

There are also embodiments of the shingle-stack type wherein the components of the stack are non-planar. FIG. 17 illustrates a shingle stack wherein the solder ball 1708 size and location may be arranged so that the die 1702, 1702′, 1702″ are non-parallel, thereby defining a “tan” configuration. FIG. 18 illustrates die 1802, 1802′, and 1802″ stacked along a common central axis in a non-shingle configuration., but the neighboring components of the stack are still non-planar due to the size and location of solder balls 1808. Such embodiments may help in cooling the stack.

The embodiments addressed above demonstrate to one of ordinary skill in the art that still other embodiments of the invention exist. Accordingly, embodiments of the invention are not limited except as stated in the claims.

1. A package, comprising
an electrical insulator;
a first electrically conductive contact on the insulator;
an electrically conductive connector coupled to the first contact; and
a die, comprising:
a first surface,
a second electrically conductive contact on the first surface and coupled to the connector, and
an electrical conductor extending from the first surface, through the die, to a second surface opposite the first surface.

2. The package in claim 1, wherein the conductor extends from the first contact, through the die, to the second surface.

3. The package in claim 2, wherein the die is configured to detect radiation along a range of wavelengths; and
the insulator comprises a material that is transparent to at least a portion of the wavelengths.

4. The package in claim 3, wherein the first contact is electrically isolated from any discrete and integral conductive traces extending along the insulator.

5. The package in claim 4, wherein the connector is generally spherical

6. The package in claim 5, wherein the connector wets to the first contact and the second contact.

7. (canceled)

8. A conductive pattern for a workpiece comprising silicon, the pattern consisting of a plurality of electrically conductive pads on the workpiece.

9. A method of assembling an imager package, comprising:
forming an imager on and within a first substrate, the imager comprising a contact on the first substrate and an electrical conductor through the substrate;
singulating the imager from the first substrate;
forming a pad on a portion of a second substrate, the second substrate comprising silicon;
singulating the portion from the second substrate;
placing a solder ball on the contact; and
placing the solder ball on the pad.

10. The method of claim 9, further comprising defining an opening through the portion of the second substrate before singulating the portion.

11. The method of claim 9, wherein the act of forming an imager comprises forming an imager with a plurality of contacts;
the act of forming a pad comprises forming a plurality of pads;
the act of placing the solder ball on the pad comprises placing a plurality of solder balls on the corresponding plurality of pads, wherein an adjacent pair of the plurality of solder balls define an opening;
attaching the imager to a third substrate after the acts of placing a solder ball on the contact and placing the solder ball on the pad; and
retaining the opening at least until the act of attaching the imager to a third substrate.

12. The method of claim 9, wherein the act of forming a pad on a portion of a second substrate comprises forming a pad on a portion of a glass substrate.

13. The method of claim 12, further comprising placing the imager on the second substrate after singulating the imager and before singulating the portion of the glass substrate.

14. The method of claim 9, wherein the act of forming a pad on a portion of a second substrate comprises forming a pad on a portion of a substrate comprising monocrystalline silicon.

15-16. (canceled)

17. A die stack, comprising:
a first die; and
a second die coupled to and over the first die, wherein:
the second die comprises:
a first end, and
a second end, and
a distance between the first die and the second die varies from the first end to the second end by more than five microns.

18. The die stack of claim 17, further comprising a plurality of solder balls coupling the first die and the second die, wherein two solder balls of the plurality differ in diameter by more than five microns.

19. The die stack of claim 18, wherein:
the first die comprises an image sensor; and
the second die comprises glass.

20. The die stack of claim 18, wherein:
the first die comprises a first portion of circuitry; and
the second die comprises a second portion of circuitry.

21. The die stack of claim 20, wherein:
the first die comprises memory circuitry; and
the second die comprises microprocessor logic circuitry.

22. The die stack of claim 20, wherein:
the first die comprises a first portion of memory circuitry; and
the second die comprises a second portion of memory circuitry.

23-24. (canceled)

25. A cover for a sensor, comprising:
a plurality of components stacked over the sensor, wherein each component of the plurality allows light to pass therethrough;
at least one component comprises a plurality of electrically conductive traceless pads on at least one side of the component; and
at least one pair of neighboring components define a distance therebetween varying by at most five microns.

26. The cover in claim 25, wherein at least one component of the plurality is transparent.

27. The cover in claim 26, wherein at least one transparent component of the plurality is a lens.

28. The cover in claim 26, wherein at least one component of the plurality defines a central opening and is located between two transparent components.

29. The cover in claim 25, wherein every pair of neighboring components define a distance varying by at most five microns.

30. The cover in claim 29, wherein each component comprises a plurality of electrically conductive pads on opposing sides of each component.

31-35. (canceled)
